(19) United States
(12) Patent Application Publication
(10) Pub. No.: US 2024/0118109 A1
(43) Pub. Date: Apr. 11, 2024

(54) Method and device for detecting axial and/or radial magnetic fields acting relative to an axis

(71) Applicant: Balluff GmbH, Neuhausen a.d.F. (DE)

(72) Inventors: Ulrich Ritter, Tubingen (DE); Shangping Ying, Boblingen (DE)

(21) Appl. No.: 18/373,508

(22) Filed: Sep. 27, 2023

(30) Foreign Application Priority Data
Oct. 6, 2022 (DE) 102022125846.7

(51) Int. Cl. G01D 5/14; F15B 15/28

(52) U.S. Cl. CPC G01D 5/14; F15B 15/2861

(57) ABSTRACT

A device for detecting axial and/or radial magnetic fields acting relative to an axis (A) is characterised by at least two magnetic switch components (530, 531) arranged adjacent to one another along the axis (A) and an evaluation circuit for combining the signals of the magnetic switch components (530, 531) to form an output signal representing a switch-on and switch-off process.

The invention relates to a device for detecting axial and/or radial magnetic fields acting relative to an axis. The invention also relates to a method for detecting axial and/or radial magnetic fields acting relative to an axis.

Such devices and methods are used, for example, in magnetic field sensors for pneumatic cylinders. They are used to identify a discrete piston position. In this case, a magnet, in particular an annular magnet, is integrated into the piston and the piston position is determined by detecting the magnetic field of this annular magnet. Detecting axial magnetic fields is readily possible for example with magnetic switch components that are known per se. However, if the magnetic field has a radial orientation, the use of magnetic switch components results in ambiguity in the output signal. Radial magnetic fields are therefore detected, for example, using 3D magnetic sensors, such as 3D Hall effect sensors. The problem here is that such 3D magnetic sensors, e.g. 3D Hall effect sensors, are significantly more expensive than simple magnetic switch components.

The invention is therefore based on the object of refining a device and a method for detecting axial and, in particular, radial magnetic fields acting relative to an axis in such a way that it is even possible to precisely detect radial magnetic fields using the most cost-effective means possible, in particular using simple magnetic switch components.

### DISCLOSURE OF THE INVENTION

The invention achieves this object using a device for detecting axial and/or radial magnetic fields acting relative to an axis, which device is characterised by at least two magnetic switch components arranged adjacent to one another along the axis and an evaluation circuit for combining the signals of the magnetic switch components to form an output signal representing a switch-on and switch-off process. Such a device makes it possible to resolve the ambiguity of the switching signal of simple magnetic switch components even with magnetic fields acting radially to the axis. This makes it possible to use cost-effective magnetic switch components to detect magnetic fields that can be aligned both radially and axially relative to the axis. In other words, the device makes it possible to detect the magnetic field independently of the orientation of the magnetic field. The device can therefore be used, for example, to detect a piston position of, e.g., a pneumatic cylinder independently of the magnets installed in the piston, i.e. whether the latter is oriented axially or radially. This can eliminate the need to use more sophisticated and more expensive components, such as 3D Hall effect sensors.

Advantageous embodiments are the subject matter of the dependent claims that refer back to claim 1. Thus, one advantageous embodiment provides that the signals of the magnetic switch components are combined with one another by way of an OR operation. The combination by way of a logical “OR” operation makes it possible to easily combine the signals of the two magnetic switch components to form an output signal representing a single switch-on and switch-off process in each case.

As an alternative to an OR operation, provision can also be made to detect rising and falling edges of each of the signals of the two magnetic switch components and, on identification of two rising edges of each of the signals of the two magnetic switch components, to conclude that a switch-on process has occurred and, on identification of two falling edges of each of the signals of the two magnetic switch components, to conclude that a switch-off process has occurred, and thus to combine the signals of the two magnetic switch components to form an output signal representing a switch-on and switch-off process.

According to one aspect of the invention it is provided that the magnetic switch components are arranged along the axis with such a spacing that when a magnet moves past the magnetic switch components along the axis, a continuous output signal results from the combination of the signals of the magnetic switch components.

Here, arranged “along the axis” does not just mean that the magnetic switches are arranged in succession in a row along the axis. Strictly in principle, they can also be arranged offset to each other simultaneously in the axial and radial direction. In any case, they must be arranged in such a way that when a magnet moves past the magnetic switch components along the axis, the output signals of the magnetic switch components are combined in such a way as to result in a continuous output signal.

The invention is not restricted to the arrangement of two magnetic switch components arranged adjacent to one another along the axis. In principle, more than two magnetic switch components can also be arranged along the axis in order to thereby increase the output signal width.

The invention also relates to a method for detecting axial and/or radial magnetic fields acting relative to an axis, wherein at least two magnetic switch components are arranged adjacent to one another along the axis, the output signals of the magnetic switch components are combined with one another by way of an OR operation to form an output signal, and thereafter the spacing along the axis is chosen to be such that the path of this output signal is continuous when a magnet moves past the magnetic switch components along the axis.

By using at least two orientation-independent magnetic switch components that are arranged spatially slightly offset, it is possible to arrange the detection ranges such that a continuous switching range can be achieved by combining the output signals of the magnetic switch components by way of the OR operation.

In order to further increase or adjust the output signal width, according to one advantageous embodiment of the method, provision can be made to arrange more than two magnetic switch components along the axis.

### DRAWINGS

Exemplary embodiments of the invention are illustrated in the drawings and explained in more detail in the following description. In the drawings:

FIG. 1 schematically shows an arrangement, known from the prior art, of a piston-cylinder assembly and of a magnetic switch component for detecting the piston position.

FIG. 2 schematically shows the effect of the arrangements of magnets on the output signal of a magnetic switch component.

FIG. 3 shows the magnetic flux density as a function of the position and the magnetic field orientation.

FIG. 4 schematically shows the arrangement as per the invention of magnetic switch components on a piston-cylinder assembly.

FIG. 5 schematically shows the effect of the direction of the magnetic field on magnetic switch components of a device according to the invention for detecting axial and/or radial magnetic fields relative to an axis.

### DESCRIPTION OF EXEMPLARY EMBODIMENTS

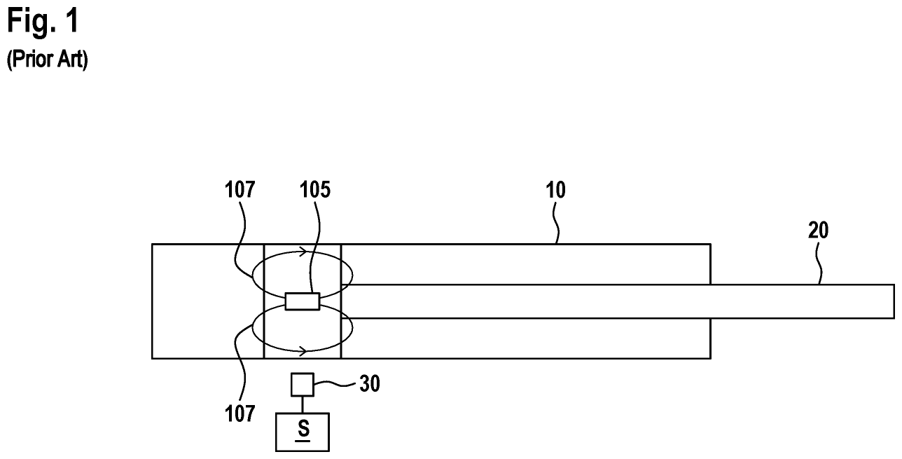

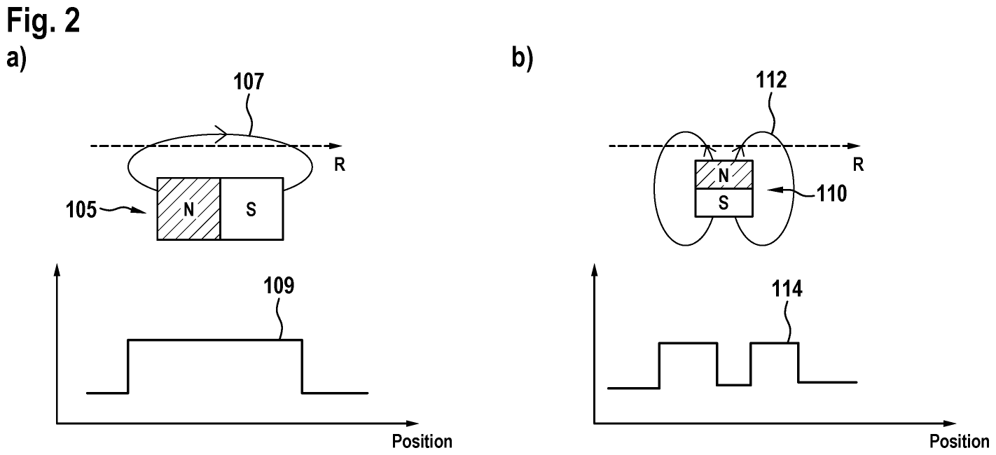

FIG. 1 is a schematic illustration of a piston-cylinder assembly comprising a cylinder 10 in which a piston 20 can move. The piston 20 has a magnet 105 which generates a magnetic field 107. Arranged adjacent to the piston-cylinder assembly 10 is a magnetic switch component 30 which detects the position of the piston 20 and the output signal of which is evaluated in a circuit S. Whenever the magnet 105 and thus its magnetic field 107 is moved past the magnetic switch component 30, the magnetic switch component 30 outputs a signal 109, as is schematically shown at the bottom of FIG. 2a. FIG. 2a illustrates the axial arrangement of the magnets 105.

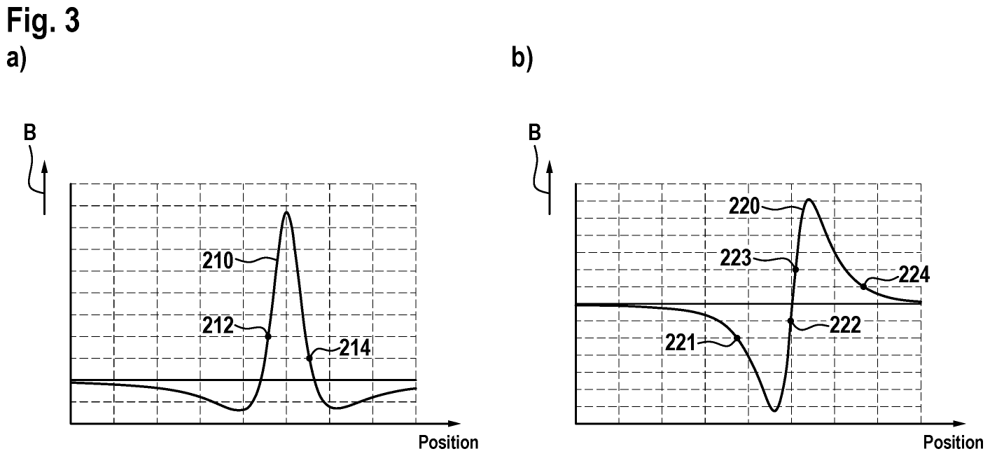

If the magnet in the piston 20 now has a radial rather than an axial orientation, as is shown at the top in FIG. 2b by way of the magnet designated 110, and if this magnet has a magnetic field 112 which—in comparison to the arrangement shown at the top in FIG. 2a—is oriented perpendicular to the magnetic switch component 30, a signal is produced which is shown at the bottom in FIG. 2b. This means that there is not just one single switching process; rather multiple switching occurs, which is undesirable. This multiple switching is explained briefly below in connection with FIG. 3. In FIG. 3a, the magnetic flux versus the position of the piston 20 is shown on the left in the case of an axial orientation of the magnet 105, as is shown at the top in FIG. 2a. A switch-on point 212 and a switch-off point 214 are defined. This results in a switching process, as is shown schematically at the bottom in FIG. 2a.

If, however, the magnet has a radial orientation, the path of the magnetic flux B is as shown in FIG. 3b. In this case, a first switch-on point 221, a first switch-off point 222 as well as a second switch-on point 223 and a second switch-off point 224 are produced. The second switch-on point 223 is offset from the first switch-off point 222, so that an undesirable multiple switching occurs, as is shown schematically at the bottom in FIG. 2b.

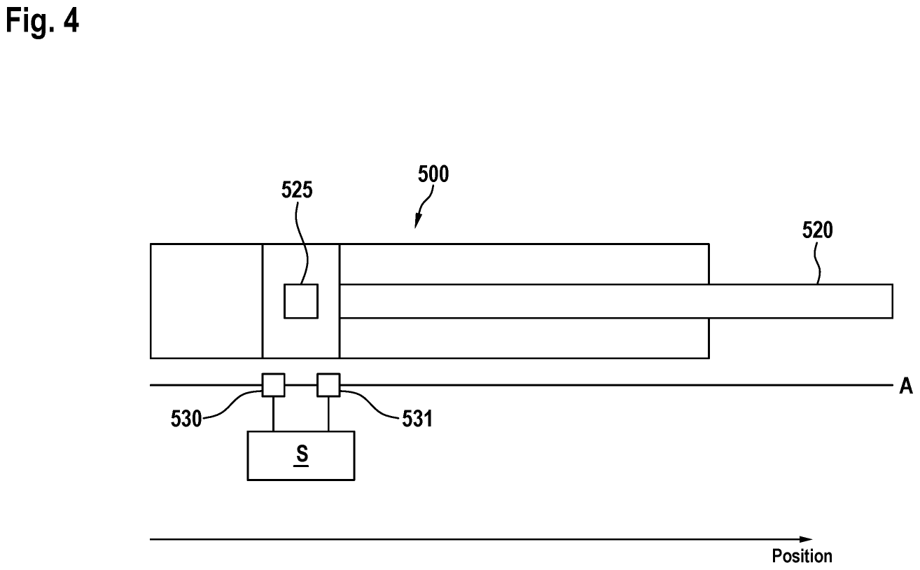

In order now to be able to detect the piston position independently of the field direction of the magnet installed in the piston, the solution according to the invention provides for arranging two magnetic switches 530, 531 next to each other, as is shown schematically in FIG. 4. FIG. 4 shows a piston-cylinder assembly 500 in which a piston 520 whose position is to be defined moves. A magnet 525, the field of which can be aligned both radially and axially, is arranged in the piston 520. Arranged adjacent to the piston-cylinder assembly 500 along an axis A are two magnetic switch components arranged adjacent to one another, the output signals of which are evaluated in the evaluation circuit S. In FIG. 4, these two magnetic switch components 530, 531 are arranged in succession on the axis A. However, such an arrangement is not absolutely necessary. It is also possible to additionally arrange the two magnetic switches 530, 531 offset to one another in the radial direction. However, the spacing along the axis A must then be chosen to be such that the path of the output signal is continuous when the magnet 525 moves past the magnetic switch components 530, 531.

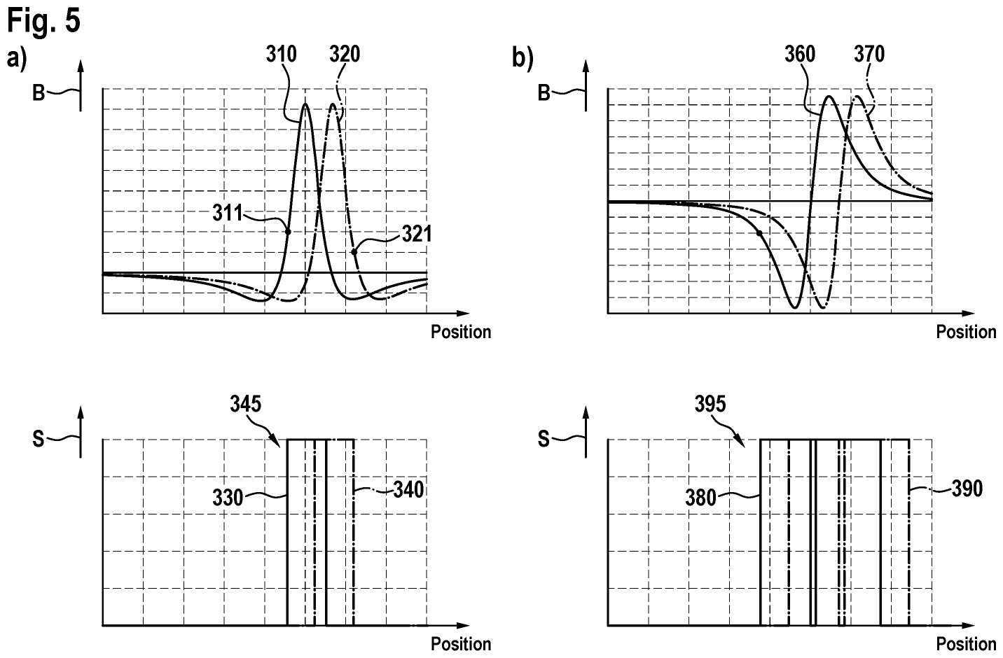

The device in FIG. 4 and the method for detecting axial and/or radial magnetic fields acting relative to the axis A is explained hereinbelow in connection with FIG. 5. The magnetic flux versus the position of the magnet 525 and thus the position of the piston 520 is shown top left in FIG. 5a, as detected by two magnetic switch components 530, 531 arranged adjacent to one another. The output switching signal of the two magnetic switch components 530, 531 is shown bottom left in FIG. 5a. Thus, the first magnetic switch component 530 switches with a switching signal 330 and the second magnetic switching signal 531 switches a switching signal 340. These two switching signals are now combined in an OR operation, resulting in the output switching signal 345 shown in FIG. 5a which has a continuous path. There is exactly one switch-on point 311 and one switch-off point 321, so that it is unequivocally possible to detect the piston position.

If the magnet 525 is now arranged in the piston 520 such that its magnetic field is oriented radially to the piston 520 and thus perpendicularly to the axis A, then a magnetic flux B is detected in the magnetic switch components 530, 531, as shown at the top in FIG. 5b. The first magnetic switch component 530 detects a magnetic flux B 360 and the second magnetic switch component 531 detects a magnetic flux B 370. The output signals of the two magnetic switch components 530, 531 are shown at the bottom in FIG. 5b. Two respective switch-on and switch-off processes occur in each of the two magnetic switch components 530, 531, which, however, are combined to form a single continuous signal 395 because of the adjacent arrangement of the magnetic switch components 530, 531 and the OR operation of the output signals. The signals 380 of the first magnetic switch component 530 overlap with the signals 390 of the second magnetic switch component which results in just a single switch-on and switch-off point, thereby making a precise detection of the position of the piston 520 possible.

The two magnetic switch components 530, 531 are arranged in this case along the axis—as mentioned—with such a spacing from one another that when the magnet 525 in the piston 520 moves past the magnetic switch components 530, 531 along the axis A, a continuous output signal 395 results from the combination of the signals of the magnetic switch components. This continuous output signal 395 is realised by the OR-connection of the output signals 380, 390 of the two magnetic switch components 530, 531.

According to one embodiment of the invention, instead of the OR operation, the switching signals of the two magnetic switch components 530, 531 can also be used to determine the output signal. For example, a switch-on process can be assumed if two rising edges of the signals of the two magnetic switch components 530, 531 are detected and a switch-off process can be assumed if two falling edges of the signals of the two magnetic switch components 530, 531 are detected.

The arrangement of two magnetic switch components 530, 531 along the axis A has been described above. It should be noted that the invention is not restricted to the arrangement of two magnetic switch components, but strictly in principle more than two, in particular a plurality of magnetic switch components, can also be arranged in order to increase the output signal width. The output signal width can be adjusted by arranging more than two magnetic switch components along the axis A.

The above-described device and the method for detecting axial and/or radial magnetic fields acting relative to an axis has the advantage that with simple magnetic switch components, both magnets whose magnetic field is provided in the axial direction and magnets whose magnetic field is provided in the radial direction in, for example, the piston of a piston-cylinder assembly can be detected. More sophisticated and more expensive components, such as 3D Hall effect sensors, do not need to be used in this case. Because very inexpensive magnetic switch components are used, the device is also particularly suitable for cost-effective mass use.

1. Device for detecting axial and/or radial magnetic fields acting relative to an axis (A), comprising:
at least two magnetic switch components (530, 531) arranged adjacent to one another along the axis; and
an evaluation circuit (S) for combining signals of the at least two magnetic switch components (530, 531) to form an output signal representing a switch-on and switch-off process.

2. Device according to claim 1, wherein an OR-operation of the signals of the at least two magnetic switch components (530, 531) is performed in the evaluation circuit (S).

3. Device according to claim 1, wherein in the evaluation circuit (S) a switch-on process is concluded when two rising edges of the signals of the at least two magnetic switch components (530, 531) are detected and a switch-off process is concluded when two falling edges of the signals of the at least two magnetic switch components (530, 531) are detected.

4. Device according to claim 1, wherein the at least two magnetic switch components (530, 531) are arranged along the axis (A) with such a spacing that, when a magnet (525) moves past the at least two magnetic switch components (530, 531) along the axis (A), a continuous output signal (345; 395) results from a combination of the signals of the at least two magnetic switch components (530, 531).

5. Device according to claim 1, wherein to increase a width of the continuous output signal, more than two magnetic switch components are arranged along the axis (A).

6. Method for detecting axial and/or radial magnetic fields acting relative to an axis (A), said method comprising the following steps:
arranging at least two magnetic switch components (530, 531) adjacent to one another along the axis (A),
combining output signals of the at least two magnetic switch components (530, 531) with one another to form an output signal (345; 395) representing a switch-on and switch-off process,
choosing spacing along the axis (A) such that a path of the output signal (345; 395) is continuous when a magnet moves past the at least two magnetic switch components along the axis.

7. The method according to claim 6, wherein the output signals of the at least two magnetic switch components (530, 531) are combined with one another by way of an OR-operation to form an output signal representing a switch-on and switch-off process.

8. The method according to claim 6, wherein the output signals of the at least two magnetic switch components (530, 531) are combined with one another in such a way that on identification of rising edges of the output signals of the at least two magnetic switch components (530, 531), it is concluded that a switch-on process has occurred and that on detection of falling edges of the output signals of the at least two magnetic switch components (530, 531), it is concluded that a switch-off process has occurred, and an output signal representing this switch-on and switch-off process is output.

9. The method according to claim 6, wherein an output signal width is adjusted by arranging more than two magnetic switch components along the axis.
